(19) United States
(12) Patent Application Publication
(10) Pub. No.: US 2015/0325457 A1
(43) Pub. Date: Nov. 12, 2015

(54) Method of Packaging Semiconductor Devices and Apparatus for Performing the Same

(71) Applicant: Dongbu Hitek Co., Ltd., Seoul (KR)

(72) Inventors: Jun Il Kim, Gyeonggi-do (KR); Sung Jin Kim, Gyeonggi-do (KR); Hag Mo Kim, Gyeonggi-do (KR)

(21) Appl. No.: 14/477,366

(22) Filed: Sep. 4, 2014

(30) Foreign Application Priority Data
May 9, 2014 (KR) 10-2014-0055229

(51) Int. Cl. H01L 21/54; H01L 21/67; H01L 23/373; H01L 21/66; H01L 23/42

(52) U.S. Cl. CPC H01L 21/54; H01L 22/22; H01L 23/42; H01L 23/373; H01L 21/6715

(57) ABSTRACT

Provided are an apparatus and method of packaging semiconductor devices mounted on a flexible substrate having a longitudinally extending tape shape and on which packaging areas are defined along the extending direction thereof. The flexible substrate is transferred through a packaging module. An empty area, on which a semiconductor device is not mounted, is detected by a camera from among the packaging areas. Heat dissipation paint composition is applied on at least one semiconductor device located in a processing region of the packaging module by a screen printing process. Thus, a heat dissipation layer configured to package the semiconductor device is formed. Here, operations of the packaging module are controlled by a control unit so that the packaging process is omitted with respect to the empty area.

### CROSS-REFERENCE TO RELATED APPLICATION

This application claims priority to Korean Patent Application No. 10-2014-0055229 filed on May 9, 2014 and all the benefits accruing therefrom under 35 U.S.C. §119, the contents of which are herein incorporated by reference in their entirety.

### BACKGROUND

The present disclosure relates to a method of packaging semiconductor devices and an apparatus for performing the same, and more particularly, to a method of packaging semiconductor devices mounted on a flexible substrate, such as a chip on film (COF) tape, a tape carrier package (TCP) tape or the like, and an apparatus for performing the same.

Generally, a display apparatus such as a liquid crystal display (LCD) may include a liquid crystal panel and a backlight unit disposed on a rear of the liquid crystal panel. Semiconductor devices such as driver integrated circuits (IC) may be employed to drive the liquid crystal panel. These semiconductor devices may be connected to the liquid crystal panel using packaging techniques such as COF, TCP, chip on glass (COG), and the like.

High resolution display devices may require an increased driving load to be provided by the semiconductor device. In the particular case of COF-type semiconductor packages, this increased driving load may cause increased heat generation, leading to problems associated with the need for increased heat dissipation.

To address the need for increased heat dissipation, some prior art methods have been developed that involve the addition of a heat sink using an adhesion member. For example, Korean Laid-Open Patent Publication No. 10-2009-0110206 discloses a COF type semiconductor package including a flexible substrate, a semiconductor device mounted on the top surface of the flexible substrate and a heat sink mounted on the bottom surface of the flexible substrate by using an adhesion member.

However, heat sinks mounted on the bottom surface of flexible substrate may be inefficient due to the relatively low thermal conductivity of the flexible substrate. In addition, such heat sinks typically have a plate shape made by using a metal such as aluminum, which may reduce the flexibility of the COF type semiconductor package. Furthermore, over time and through normal use, the heat sink may become separated from the flexible substrate.

### SUMMARY

The present disclosure provides a packaging method that improves the heat dissipation efficiency of the semiconductor devices and an apparatus for performing the packaging method.

In accordance with some exemplary embodiments, a method of packaging semiconductor devices may include transferring the flexible substrate through a packaging module; detecting an empty area, on which a semiconductor device is not mounted, from among the packaging areas; and forming a heat dissipation layer on at least one semiconductor device located in a processing region of the packaging module so as to package the semiconductor device. The heat dissipation layer may be formed by coating the semiconductor device with a heat dissipation paint composition by using a screen printing process, and a packaging process on the empty area may be omitted. The semiconductor devices may be mounted on a flexible substrate having a longitudinally extending tape shape and on which packaging areas are defined along an extending direction thereof.

In some exemplary embodiments, the forming of the heat dissipation layer may include disposing a mask having an opening which exposes the semiconductor device and a portion of a top surface of the flexible substrate that is adjacent to the semiconductor device on the flexible substrate. Formation of the heat dissipation later may further include depositing the heat dissipation paint composition onto the mask, and filling the opening with the heat dissipation paint composition using a squeegee.

In exemplary embodiments, the processing region of the packaging module may include a plurality of screen printing regions. The screen printing process on the remaining packaging areas may be performed simultaneously, except for the empty area.

In some exemplary embodiments, the screen printing regions may be isolated from each other.

In some exemplary embodiments, the method may further include curing the heat dissipation layer formed on the semiconductor device.

In some exemplary embodiments, the method may further include forming an underfill layer that fills a space defined between the flexible substrate and the semiconductor device.

In some exemplary embodiments, the underfill layer may be formed by injecting an underfill resin into the space between the flexible substrate and the semiconductor device.

In some exemplary embodiments, the forming of the underfill layer may include transferring the flexible substrate through an underfill module disposed prior to the packaging module, and forming the underfill layer between the packaging area of the flexible substrate and the semiconductor device located in a processing region of the underfill module. An underfill process may be omitted on the empty area.

In some exemplary embodiments, a plurality of packaging areas may be located in the processing region of the underfill module, and the underfill process may be performed simultaneously on the semiconductor devices mounted on the remaining packaging areas. The underfill process may be omitted on the empty area.

In some exemplary embodiments, the method may further include curing the underfill layer.

In some exemplary embodiments, the heat dissipation paint composition may include approximately 1 wt % to approximately 5 wt % of an epichlorohydrin bisphenol A resin, approximately 1 wt % to approximately 5 wt % of a modified epoxy resin, approximately 1 wt % to approximately 10 wt % of a curing agent, approximately 1 wt % to approximately 5 wt % of a curing accelerator and the remaining amount of a heat dissipation filler.

In some exemplary embodiments, the modified epoxy resin may be a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), a urethane modified epoxy resin or a silicon modified epoxy resin.

In some exemplary embodiments, the curing agent may be a novolac type phenolic resin.

In some exemplary embodiments, the curing accelerator may be an imidazole-based curing accelerator or an amine-based curing accelerator.

In some exemplary embodiments, the heat dissipation filler may include aluminum oxide having a particle size of approximately 0.01 μm to approximately 50 μm.

In accordance with another exemplary embodiment, an apparatus for packaging semiconductor devices may be provided. The semiconductor devices may be mounted on a flexible substrate having a longitudinally extending tape shape and on which packaging areas are defined along an extending direction thereof. The apparatus may include an unwinder module configured to supply the flexible substrate, a rewinder module configured to recover the flexible substrate, and a packaging module disposed between the unwinder module and the rewinder module to coat the semiconductor devices with a heat dissipation paint composition by using a screen printing process. The packaging module may thereby form heat dissipation layers packaging the semiconductor devices. The apparatus may further include a control unit configured to detect an empty area on which a semiconductor device is not mounted from among the packaging areas and to control operations of the packaging module so that a packaging process is omitted on the empty area.

In some exemplary embodiments, the packaging module may include a packaging chamber and a screen printing unit disposed in the packaging chamber. The screen printing unit may include a mask defining an opening configured to apply the heat dissipation paint composition on the semiconductor devices. The screen printing unit may also include a nozzle configured to supply the heat dissipation paint composition on the mask, and a squeegee configured to fill the opening with the heat dissipation paint composition. The packaging module may also include a driving unit configured to vertically move the screen printing unit so as to be disposed on the flexible substrate and to horizontally move the squeegee so as to fill the opening with the heat dissipation paint composition.

In some exemplary embodiments, the apparatus may further include a curing module configured to cure the heat dissipation layers.

In some exemplary embodiments, the curing module may include a curing chamber disposed between the packaging module and the rewinder module, and a plurality of heaters disposed along a transfer path of the flexible substrate in the curing chamber to cure the heat dissipation layers.

In some exemplary embodiments, the apparatus may further include an underfill module configured to form underfill layers between the flexible substrate and the semiconductor devices.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE DRAWINGS

Exemplary embodiments can be understood in more detail from the following description taken in conjunction with the accompanying drawings, in which:

FIG. 1 depicts a schematic view of an apparatus adequate for performing a method of packaging semiconductor devices in accordance with some exemplary embodiments;

FIG. 2 depicts a schematic view of a flexible substrate of FIG. 1 in accordance with some exemplary embodiments;

FIG. 3 depicts a schematic plan view of a screen printing unit of FIG. 1 in accordance with some exemplary embodiments;

FIGS. 4 to 6 depict schematic side views of the screen printing unit of FIG. 1 in accordance with some exemplary embodiments;

FIGS. 7 and 8 depict schematic front views illustrating an operation of a packaging module of FIG. 1 in accordance with some exemplary embodiments;

FIG. 9 depicts a schematic front view illustrating a modified example of operations of the screen printing units of FIG. 7 in accordance with some exemplary embodiments;

FIGS. 10 to 12 depict schematic cross-sectional views illustrating a method of packaging semiconductor devices in accordance with an exemplary embodiment in accordance with some exemplary embodiments;

FIGS. 13 and 14 depict photographs of a semiconductor package manufactured by the method illustrated in FIGS. 10 to 12 in accordance with some exemplary embodiments;

FIG. 15 depicts a schematic view of an apparatus adequate for performing a method of packaging semiconductor devices in accordance with some exemplary embodiments; and

FIGS. 16 to 18 depict schematic cross-sectional views illustrating a method of packaging semiconductor devices in accordance with some exemplary embodiments.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will also be understood that when an element or layer is referred to as being ‘on’ another one, it can be directly on the other layer, film, region, or plate, or one or more intervening elements or layers may also be present. On the other hand, it will be understood that when an element is directly disposed on or connected to another element, further another element cannot be present therebetween. Also, though ordinal numbers such as “a first”, “a second”, and “a third” are used to describe various elements, compositions, areas and/or layers in various embodiments of the present invention, these terms are used merely for ease of reference and/or to provide antecedent basis for particular elements, regions, layers, and/or sections. Accordingly, these terms should not be construed to describe or imply a particular sequence or ordering of elements, compositions, areas and/or layers unless explicitly stated.

In the following description, the technical terms are used only for explaining specific exemplary embodiments, and are not intended to limit the present invention. Also, unless otherwise defined, all terms, including technical and scientific terms used herein are understood to have the same meaning as commonly understood by one of ordinary skill in the art to which the invention pertains. It will be further understood that terms, such as those defined in commonly used dictionaries, should be interpreted as having a meaning that is consistent with their meaning in the context of the relevant art. Such terms should not be interpreted in an overly formal sense unless expressly so defined herein.

Some example embodiments are described herein with reference to schematic illustrations of particular example embodiments. Variations from the sizes and shapes of the illustrations, as a result, for example, of manufacturing techniques and/or tolerances, are to be expected. Furthermore, these schematics are not drawn to scale. Thus, example embodiments should not be construed as limited to the particular sizes or shapes of regions illustrated herein. For example, deviations in the illustrated shapes resulting from, for example, the use of a particular production method and/or design tolerances of the process or attendant components are to be expected. As such, it should be appreciated that the regions illustrated in the figures are not intended to illustrate the actual size or shape of a region of a device, apparatus, region, or zone, and are not intended to limit the scope of the present inventive concept or claims.

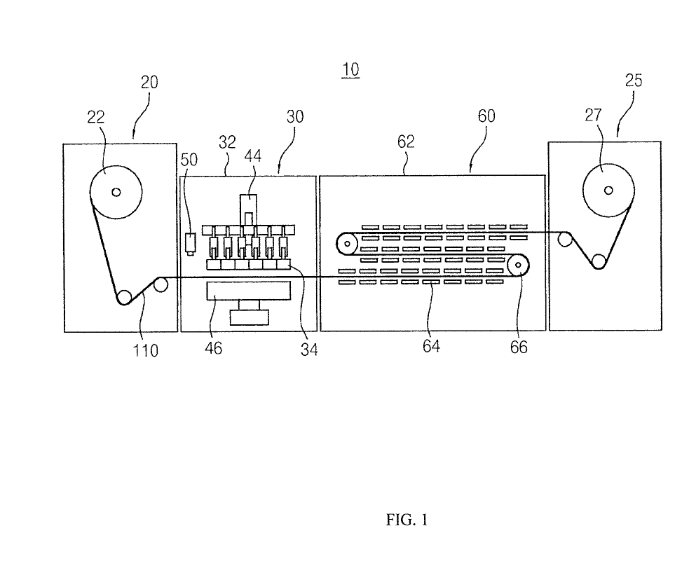

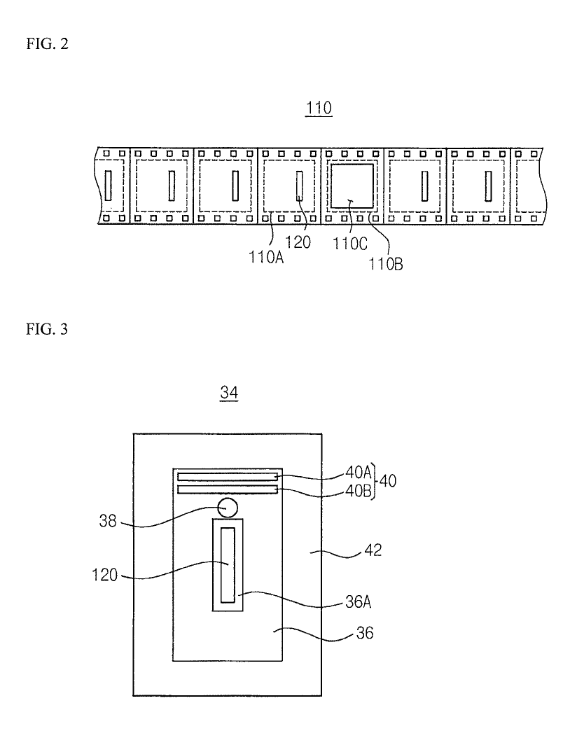

FIG. 1 depicts a schematic view of an apparatus 10 for performing a method for packaging semiconductor devices in accordance with some exemplary embodiments, and FIG. 2 depicts a schematic view of a flexible substrate as depicted in FIG. 1.

As depicted in FIGS. 1 and 2, an apparatus 10 for packaging semiconductor devices may package semiconductor devices 120 mounted on a flexible substrate 110. In particular, the flexible substrate 110 may be a chip on film (COF) type tape for manufacturing a COF type semiconductor package. Additionally or alternatively, the flexible substrate 110 may be implemented as a TCP tape, a ball grid array (BGA) tape or an application specific integrated circuit (ASIC) tape.

The flexible substrate 110 may have a longitudinally extending tape shape, and, as illustrated in FIG. 2, a plurality of packaging areas 110A may be defined extending along the length of the flexible substrate 110. The semiconductor devices 120 may be mounted on the packaging areas 110A by, for example, a die bonding process.

After performing the die bonding process, the semiconductor devices 120 mounted on the flexible substrate 110 may be inspected via an inspection process. Semiconductor devices determined to be defective may be removed from the flexible substrate 110 as a result of the inspection process. For example, the defective semiconductor devices 120 may be removed from the flexible substrate 110 by a “punching” process. As a result, the flexible substrate 110 may include one or more empty areas 110B on which the semiconductor device 120 is not mounted due to the removal of the defective semiconductor devices during the inspection process, as illustrated in FIG. 2. As a result of the “punching” process, a punch hole 110C may be formed in the empty area 110B.

The packaging apparatus 10 may include an unwinder module 20 for supplying the flexible substrate 110 and a rewinder module 25 for recovering the flexible substrate 110. The unwinder module 20 and the rewinder module 25 may include a supply reel 22 for supplying the flexible substrate 110 and a recovery reel 27 for recovering the flexible substrate 110, respectively. Further, although not shown, each of the unwinder module 20 and the rewinder module 25 may include a driving unit for rotating each of the supply reel 22 and the recovery reel 27.

A packaging module 30 may be disposed between the unwinder module 20 and the rewinder module 25. The packaging module 30 may be configured to perform a packaging process on the semiconductor devices 120. The packaging module 30 may include a packaging chamber 32. The flexible substrate 110 may be transferred lengthwise through the packaging chamber 32.

In accordance with some exemplary embodiments, heat dissipation paint composition may be applied on the semiconductor devices 120 located in the packaging chamber 32. Thus, heat dissipation layers (see, e.g., reference numeral 130 of FIG. 12) may be formed on the semiconductor devices 120 as part of the packaging process. In the presently described exemplary embodiment, the heat dissipation layers 130 may be formed by a screen printing process. For example, screen printing units 34 for coating the semiconductor devices 120 with the heat dissipation paint composition may be disposed in the packing chamber 32.

As illustrated in the drawings, six screen printing units 34 may be disposed within the packaging chamber 32. However, it should be appreciated that the number of screen printing units 34 is not intended to be limited by the drawings and that various numbers of screen printing units 34, both less than and greater than six, may be employed. For example, some embodiments may include only a single screen printing unit 34.

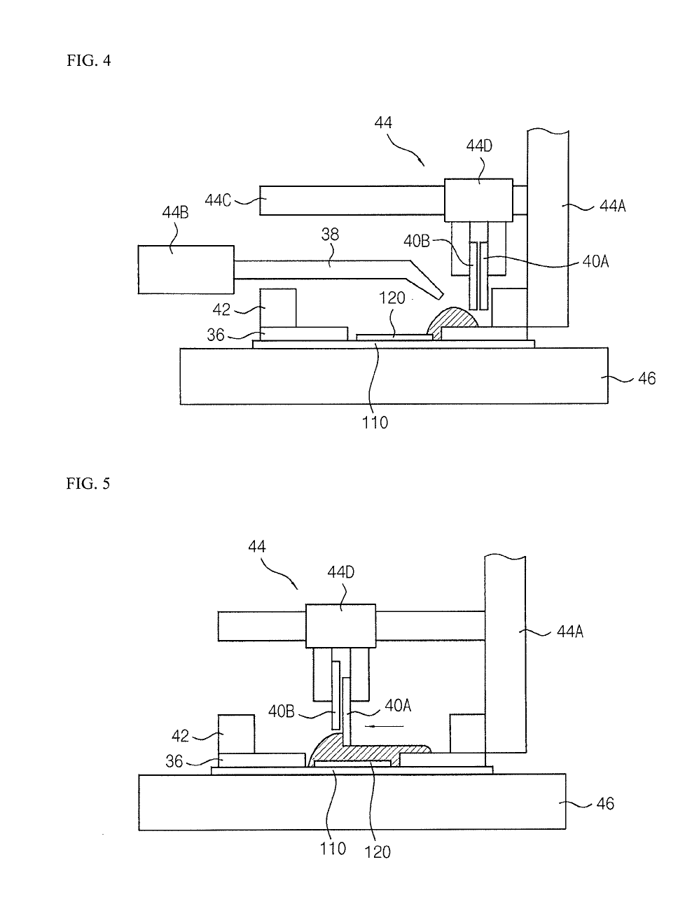

FIG. 3 depicts a schematic plan view of a screen printing unit of FIG. 1, and FIGS. 4 to 6 depict schematic side views of the screen printing unit of FIG. 1.

The screen printing unit 34 may include a mask 36 defining an opening 36A through which the heat dissipation paint composition may be applied on the semiconductor devices 120. The screen printing unit 34 may further include a nozzle 38 for supplying the heat dissipation paint composition on the mask 36, and a squeegee 40 for filling the opening 36A with the heat dissipation paint composition.

The packaging module 30 may include a packaging driving unit 44 operable to move the screen printing unit 34 in a vertical direction to place the screen printing unit 34 upon the flexible substrate 110. The packaging driving unit 44 may also be operable to move the squeegee 40 in a horizontal direction to fill the opening 36A with the heat dissipation paint composition.

In accordance with some exemplary embodiments, the screen printing unit 34 may include a screen printing region. In particular, the mask 36 may be mounted on a lower surface of a frame 42. The frame 42 may have a square ring shape, and the screen printing region may be defined by the frame 42. The frame 42 may have a predetermined thickness (e.g., 1 mm, 3 mm, 5 mm, 1 cm, or the like) to prevent the heat dissipation paint composition supplied on the mask 36 from leaking beyond the screen printing region. Also, the frame 42 may be connected to the packaging driving unit 44. As a result, the screen printing unit 34 may be isolated from other screen printing units 34 disposed adjacent to the frame 42.

The opening 36A may expose the semiconductor device 120 and a portion of a top surface of the flexible substrate 110 adjacent to the semiconductor device 120.

The packaging driving unit 44 may include a first driving unit 44A for vertically moving the screen printing unit 34, a second driving unit 44B for moving the nozzle 38, a third driving unit 44C for horizontally moving the squeegee 40, and a fourth driving unit 44D for vertically moving the squeegee 40.

The first driving unit 44A may be connected to the frame 42 to allow the screen printing unit 34 to descend so that the mask 36 is closely attached to the flexible substrate 110. The second driving unit 44B may move the nozzle 38 so that the heat dissipation paint composition is supplied at a predetermined position on the mask 36. In particular, the second driving unit 44B may move the nozzle 38 so that the squeegee 40 and the nozzle 38 do not interfere with each other.

In accordance with some exemplary embodiments, the screen printing unit 34 may include a first squeegee 40A and a second squeegee 40B to fill the inside of the opening 36A with the heat dissipation paint composition.

The first squeegee 40A may be spaced a predetermined distance in a vertical direction from the mask 36 as illustrated in FIG. 5 and be moved in a first horizontal direction by the third driving unit 44C. As the squeegee is moved in the horizontal direction, the horizontal movement may cause the heat dissipation paint composition to fill the opening 36A. As a result, the heat dissipation layer 130 for packaging the semiconductor device 120 may be formed within the opening 36A.

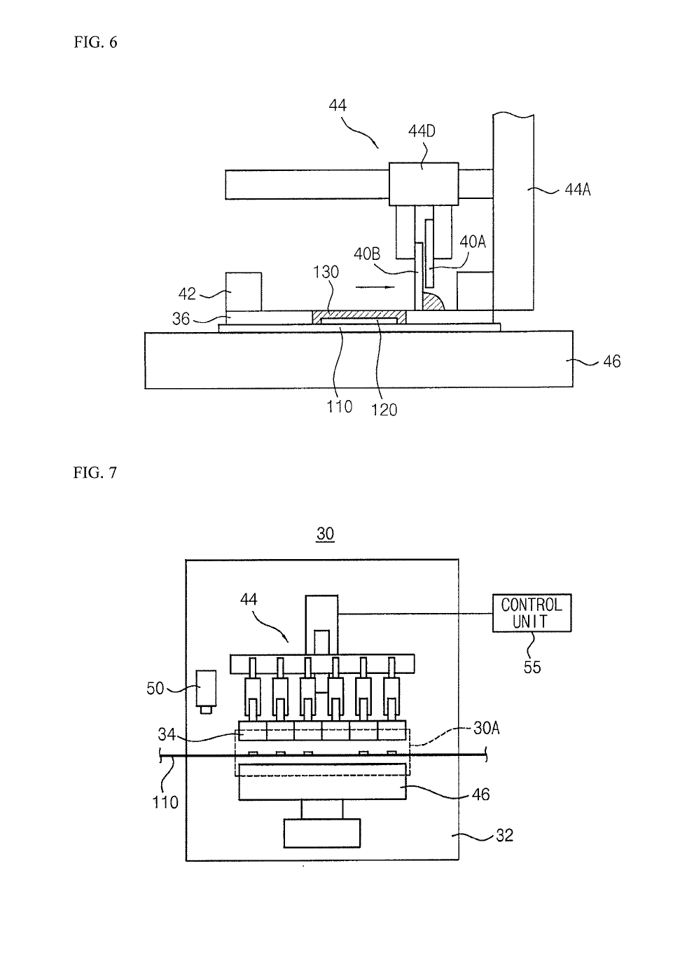

The second squeegee 40B may be moved in a second horizontal direction opposite to the first horizontal direction to remove the surplus heat dissipation paint composition remaining on the mask 36 as illustrated in FIG. 6. Here, the second squeegee 40B may be brought into close contact with a top surface of the mask 36 by the fourth driving unit 44D.

In accordance with some additional or alternative exemplary embodiments, the screen printing process may be performed using a single squeegee. For example, the fourth driving unit 44D may adjust a height of the squeegee. When the squeegee is moved in the first horizontal direction, the squeegee may be spaced a predetermined distance from the top surface of the mask 36. On the other hand, when the squeegee is moved in the second horizontal direction, the squeegee may be brought into close contact with the top surface of the mask 36.

FIGS. 7 and 8 are schematic front views illustrating an operation of a packaging module of FIG. 1. A support member 46 for supporting the flexible substrate 110 may be disposed in the packaging chamber 32. The support member 46 may have a flat top surface. As illustrated in the drawings, the support member 46 may partially support the flexible substrate 110 disposed under the screen printing units 34. The support member 46 may have a plurality of vacuum holes (not shown) to adsorb and fix a portion of the flexible substrate 110 disposed on the support member 46 by using a vacuum. In some embodiments, the support member 46 may be vertically movable to support the flexible substrate 110.

As illustrated in FIG. 7, a processing region 30A may be defined in the packaging chamber 32. The packaging process may be performed in the processing region 30A. In some embodiments, the processing region 30A may be defined between the screen printing units 34 and the support member 46. The screen printing units 34 may perform the packaging process with respect to the semiconductor devices disposed in the processing region 30A. For example, packaging areas 110A corresponding to the screen printing regions of the screen printing units 34 may be located in the processing region 30A as illustrated in the drawings. Thus, the packaging process with respect to the semiconductor devices 120 mounted on the packaging areas 110A may be performed simultaneously.

The packaging process may detect whether an empty area, such as the empty area 110B, is presented among the packaging areas 110A located in the processing region 30A. When an empty area is detected, the packaging process may be performed on the remaining packaging areas 110A other than the empty area 110B. The packaging process may occur simultaneously on the remaining packaging areas 110A.

In accordance with some exemplary embodiments, the packaging apparatus 10 may include a camera 50 and a control unit 55. The camera 50 may detect empty areas within the processing region 30A. The control unit may control operations of the packaging driving unit 44 and the screen printing units 34 to ensure that the packaging process is not performed in detected empty areas. Additionally or alternatively, information with respect to the empty area 110B may be provided into the control unit 55 prior to the packaging process. For example, data gathered during the inspection process (e.g., the locations of defective semiconductor devices) and punching process (e.g., the location of holes caused by the punching process) may be provided to the control unit 55 before packaging one or more of the semiconductor devices 120. The control unit 55 may control the operations of the packaging driving unit 44 and the screen printing units 34 by using the previously provided data and/or data detected by the camera 50.

Referring to FIG. 8, the packaging driving unit 44 may allow the screen printing units 34 to descend so that the screen printing units 34 are disposed on the flexible substrate 110. The semiconductor devices 120 on the packaging areas 110A may then be packaged by the screen printing process. However, the control unit 55 may ensure that the screen printing unit 34 corresponding to the empty area 110B is not enabled or operated during the packaging process. That is, the nozzle 38 and the squeegee 40 of the screen printing unit 34 corresponding to the empty area 110B may not operate so that the heat dissipation paint composition is not supplied into the punch hole 110C formed in the empty area 110B.

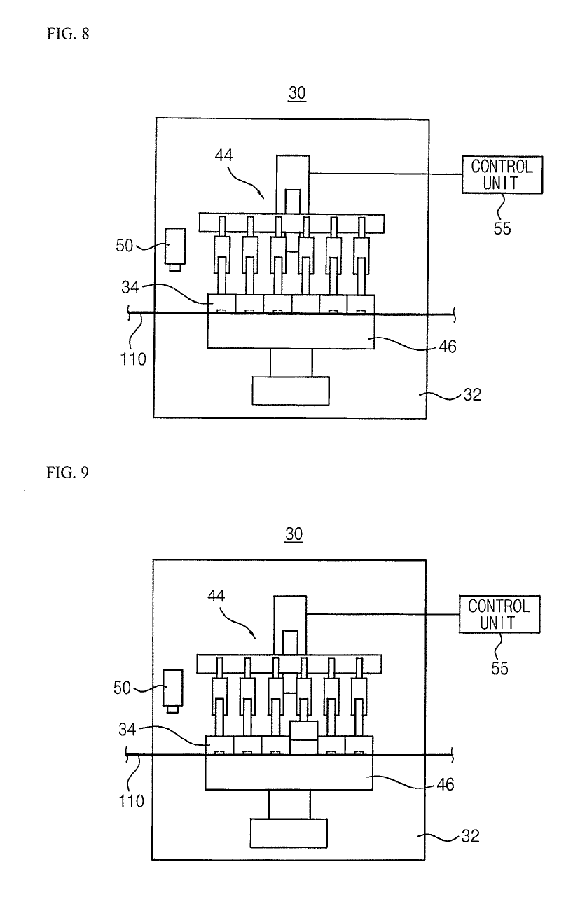

FIG. 9 depicts a schematic front view illustrating another example of operations of the screen printing units of FIG. 7. As illustrated in FIG. 9, the packaging driving unit 44 may prohibit the screen printing unit 34 corresponding to the empty area 110B of the screen printing units 34 from descending. For example, the packaging driving unit 44 may include a plurality of first driving units for moving the screen printing units 34 vertically to descend on the flexible substrate 110 during the packaging process. The control unit 55 may control each of operations of the first driving units.

Referring again to FIG. 1, the packaging apparatus 10 may include a curing module 60 for curing the heat dissipation layers 130 formed on the semiconductor devices 120. The curing module 60 may include a curing chamber 62. The flexible substrate 110 may be transferred through the curing chamber 62. The curing module 60 may include a plurality of heaters 64 disposed along a transfer path of the flexible substrate 110 within the curing chamber 62. The curing module 60 may also include rollers 66 for adjusting a transfer distance of the flexible substrate 110. For example, the flexible substrate 110 may be transferred along a transfer path having a serpentine pattern within the curing chamber 62. The heat dissipation layers 130 on the semiconductor devices 120 may be cured by the heaters 64.

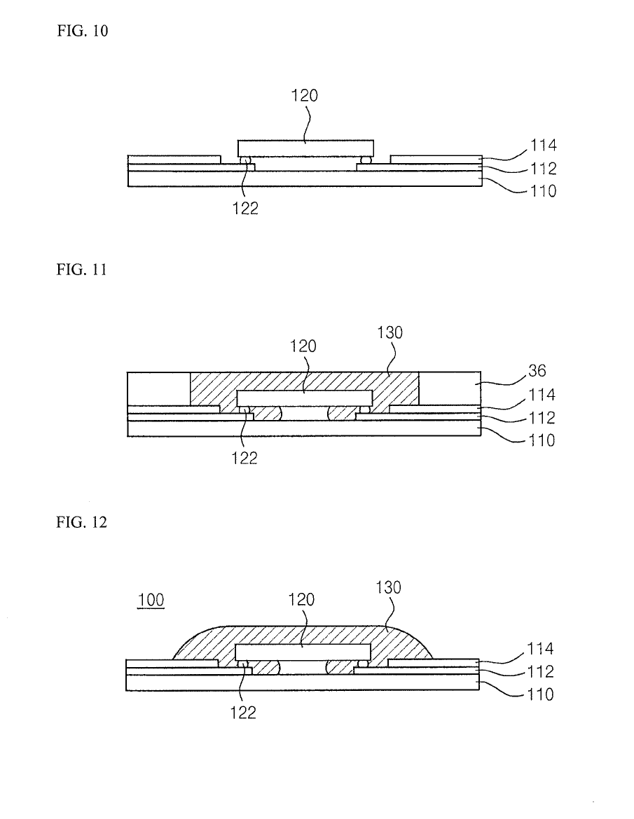

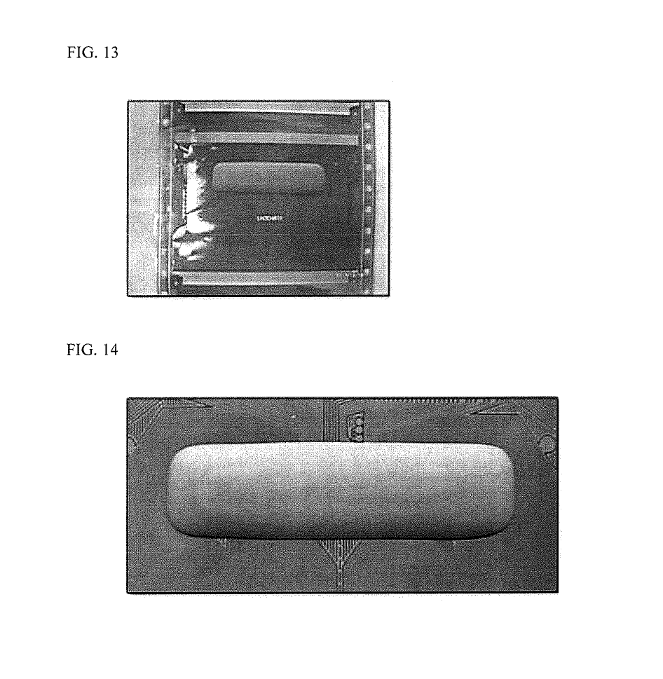

Exemplary methods for packaging the semiconductor devices 120 in accordance with some exemplary embodiments will be now described with reference to the accompanying drawings. FIGS. 10 to 12 depict schematic cross-sectional views illustrating a method of packaging semiconductor devices in accordance with an exemplary embodiment, and FIGS. 13 and 14 depict photographs of a semiconductor package manufactured by the method illustrated in FIGS. 10 to 12.

As illustrated in FIG. 1, the flexible substrate 110 may be transferred between the unwinder module 20 and the rewinder module 25 through the packaging module 30 and the curing module 60. As depicted above, a semiconductor device 120 may be mounted on each of the packaging areas 110A of the flexible substrate 110.

Signal lines 112, such as conductive patterns, may be disposed on the flexible substrate 110. Further, an insulation layer 114 for protecting the signal lines 112 may be disposed on the flexible substrate 110. As illustrated in FIG. 10, the semiconductor devices 120 may be bonded to the flexible substrate 110 so that the semiconductor devices 120 are connected to the signal lines 112 through gold bumps and/or solder bumps 122. For example, each of the signal lines 112 may be formed of a conductive material such as copper. The insulation layer 114 may be a surface resist (SR) layer or a solder resist layer.

An empty area 110B, on which the semiconductor device 120 is not mounted, may be detected by the camera 50 from among the packaging areas 110A. The packaging process may then be performed with respect to the semiconductor devices 120 located in a processing region 30A of the packaging module 30 may be performed. The control unit 55 may control operations of the packing module 30 so that the packaging process is omitted with respect to the empty area 110B.

Referring to FIG. 11, the screen printing process with respect to the semiconductor devices 120 may be performed on the processing region 30A of the packaging module 30. For example, the mask 36 may define an opening 36A, through which the semiconductor device 120 and a portion of the top surface of the flexible substrate 110 adjacent to the semiconductor device 120 are exposed. The mask 36 may be disposed on the flexible substrate, and the heat dissipation paint composition may be supplied onto the mask 36 through the nozzle 38. Then, the inside of the opening 36A may be filled with the heat dissipation paint composition by using the squeegee 40.

After the screen printing process is performed, the mask 36 may be removed from the flexible substrate 110. Thus, as illustrated in FIG. 12, a heat dissipation layer 130 for packaging the semiconductor device 120 may be formed on the flexible substrate 110 and the semiconductor device 120.

While the packaging process is performed, the heat dissipation paint composition may permeate into a space between the flexible substrate 110 and the semiconductor device 120. However, if the heat dissipation paint composition does not sufficiently permeate into the space between the flexible substrate 110 and the semiconductor device 120, an air layer may be formed between the flexible substrate 110 and the semiconductor device 120 as illustrated in the drawings.

In accordance with some exemplary embodiments, the viscosity of the heat dissipation paint composition may be adjusted to ensure that the heat dissipation paint composition sufficiently permeates the space between the flexible substrate 110 and the semiconductor device 120. In such cases, an underfill layer may be formed between the flexible substrate 110 and the semiconductor device 120 by the permeation of the heat dissipation paint composition.

Referring to FIGS. 13 and 14, after the heat dissipation layers 130 are formed, the flexible substrate 110 may be transferred into the curing chamber 62. While the flexible substrate 110 is transferred through the curing chamber 62, the heat dissipation layers 130 on the semiconductor devices 120 may be sufficiently cured. The heat dissipation layers 130 may be curable at a temperature of approximately 140° C. to approximately 160° C. For example, the heat dissipation layers 130 may be cured at a temperature of approximately 150° C. Curing of the heat dissipation layers 130 may complete the packaging process, thus providing semiconductor packages 100 having improved heat dissipation characteristics and flexibility.

In accordance with some example embodiments, the heat dissipation paint composition may include an epichlorohydrin bisphenol A resin, a modified epoxy resin, a curing agent, a curing accelerator, a heat dissipation filler, and/or combinations thereof. In particular, in some exemplary embodiments the heat dissipation paint composition may include approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator and the remaining amount of the heat dissipation filler.

The use of epichlorohydrin bisphenol A resin may improve the adhesiveness of the heat dissipation paint composition, and the use of modified epoxy resin may improve the flexibility and the elasticity of the heat dissipation layer during and after the curing process. Particularly, the modified epoxy resin may include a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, an acrylic rubber modified epoxy resin (ARMER), an urethane modified epoxy resin, a silicon modified epoxy resin, and the like.

The curing agent may include a novolac type phenolic resin. For example, a novolac type phenolic resin obtained by reacting one of phenol, cresol and bisphenol A with formaldehyde may be used.

The curing accelerator may include an imidazole-based curing accelerator or an amine-based curing accelerator. For example, the imidazole-based curing accelerator may include imidazole, isoimidazole, 2-methylimidazole, 2-ethyl-4-methylimidazole, 2,4-dimethylimidazole, butylimidazole, 2-methylimidazole, 2-phenylimidazole, 1-benzyl-2-methylimidazole, 1-propyl-2-methylimidazole, 1-cyanoethyl-2-methylimidazole, 1-cyanoethyl-2-ethyl-4-methylimidazole, phenylimidazole, benzylimidazole, and the like, and combinations thereof.

The amine-based curing accelerator may include an aliphatic amine, a modified aliphatic amine, an aromatic amine, a secondary amine, a tertiary amine, and the like, and combinations thereof. For example, the amine-based curing accelerator may include benzyldimethylamine, triethanolamine, triethylenetetramine, diethylenetriamine, triethylamine, dimethylaminoethanol, m-xylenediamine, isophorone diamine, and the like, and combinations thereof.

The heat dissipation filler may include aluminum oxide having a particle size of approximately 0.01 μm to approximately 50 μm, and preferably, of approximately 0.01 μm to approximately 20 μm. The heat dissipation filler may be used to improve the thermal conductivity of the cured heat dissipation layer 130. Particularly, the heat dissipation paint composition may include approximately 75 wt % to approximately 95 wt % of the heat dissipation filler based on the total amount of the heat dissipation paint composition. The thermal conductivity of the heat dissipation layer 130 may be adjusted to be within a range of approximately 2.0 W/mK to approximately 3.0 W/mK. In addition, the adhesiveness of the heat dissipation layer 130 may be adjusted to be within a range of approximately 8 MPa and approximately 12 MPa by the epichlorohydrin bisphenol A resin and the modified epoxy resin.

The viscosity of the heat dissipation paint composition may be adjusted to be within a range of approximately 100 Pas to approximately 200 Pas, and the heat dissipation paint composition may be cured in a temperature range of approximately 140° C. to approximately 160° C. The viscosity of the heat dissipation paint composition may be measured by using a B type rotational viscometer and may be particularly measured at a rotor rotation velocity of approximately 20 rpm at a temperature of approximately 23° C.

In accordance with some exemplary embodiments, the heat dissipation layer 130 may be formed directly on the top surface and the side surfaces of the semiconductor device 120, thereby improving and the heat dissipation efficiency from the semiconductor device 120. Since the heat dissipation layer 130 has improved flexibility and adhesiveness, the likelihood of separation of the heat dissipation layer 130 from the flexible substrate 110 and the semiconductor device 120 may be reduced. Also, the flexibility of the semiconductor package 100 may be largely improved when compared to conventional packaging and heat dissipation techniques.

By detecting the presence of an empty area 110B among the packaging areas 110A, embodiments may avoid conducting the packaging process on these empty areas. As a result, embodiments may improve the productivity of the packaging process.

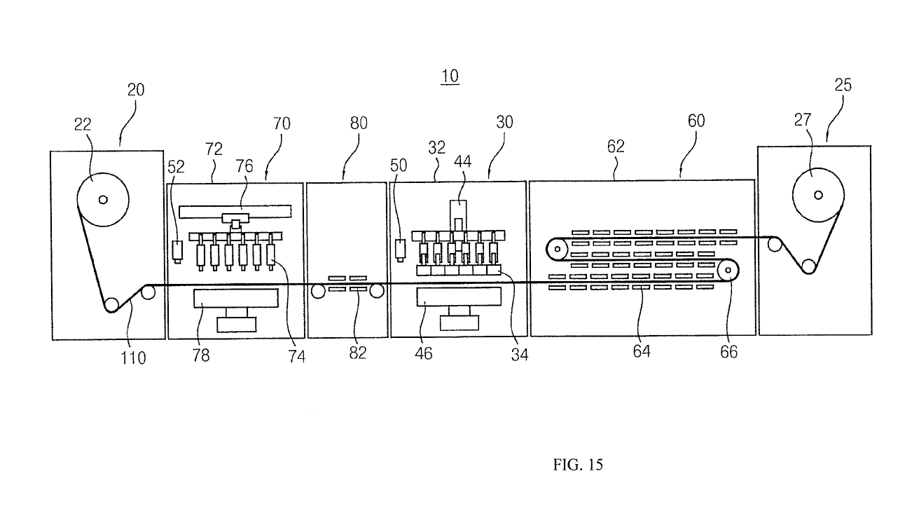

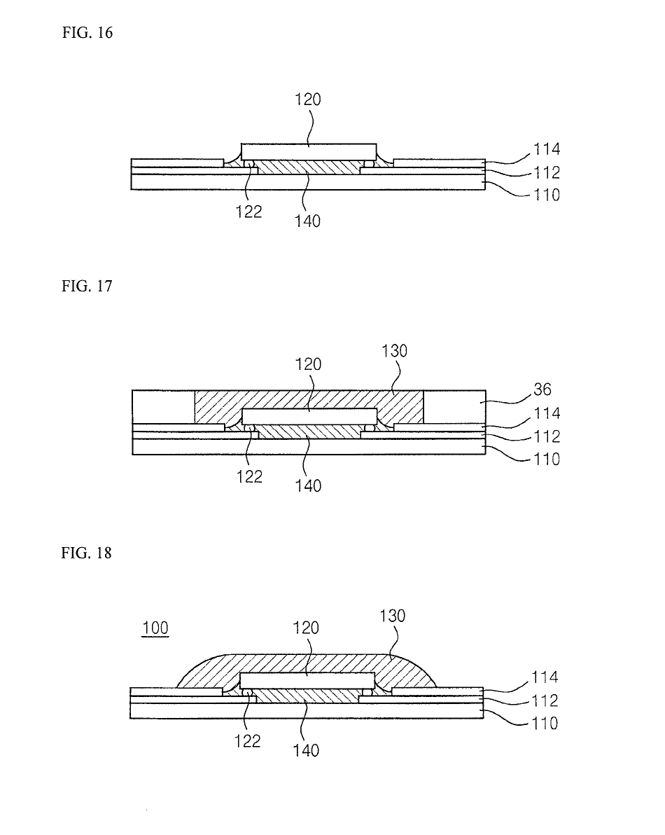

FIG. 15 depicts a schematic view of an apparatus for performing a method of packaging semiconductor devices in accordance with some exemplary embodiments, and FIGS. 16 to 18 depict schematic cross-sectional views illustrating exemplary methods for packaging semiconductor devices in accordance with some exemplary embodiments.

Referring to FIG. 15, an apparatus 10 of packaging semiconductor devices 120 may include an underfill module 70 for forming underfill layers (see reference numeral 140 of FIG. 16) between a flexible substrate 110 and the semiconductor devices 120. The apparatus 10 may also include a pre-curing module 80 for curing the underfill layers 140. The underfill module 70 and the pre-curing module 80 may be disposed between an unwinder module 20 and a packaging module 30. The flexible substrate 110 may be transferred into the packaging module 30 through the underfill module 70 and the pre-curing module 80.

The underfill module 70 may include an underfill chamber 72. The flexible substrate 110 may be horizontally transferred through the underfill chamber 72. The underfill module 70 may also include potting units 74 for injecting an underfill resin between the flexible substrate 110 and the semiconductor devices 120 disposed within the underfill chamber 72. The potting units 74 may be movable in vertical and horizontal directions by an underfill driving unit 76.

Furthermore, the apparatus 10 may include a support member 78 for supporting the flexible substrate 110. The support member 78 may be disposed in the underfill chamber 72. Although not shown, the support member 78 may have vacuum holes for adsorbing and fixing the flexible substrate 110 to the support member 78. A processing region (not shown) in which the underfill process is performed may be defined in the underfill chamber 72. The processing region may be defined between the potting units 74 and the support member 78. The underfill process may be performed simultaneously on the semiconductor devices 120 located in the processing region.

A camera 52 may be disposed in the underfill chamber 72. The camera 52 may detect an empty area 110B from among the packaging areas 110A of the flexible substrate 110. Operations of the underfill driving unit 76 and the potting units 74 may be controlled by a control unit 55. Particularly, the control unit may control the underfill driving unit 76 and the potting units 74 so that the underfill process is not performed on the empty area 110B.

The underfill driving unit 76 may allow the remaining potting units 74, aside from any potting units disposed over the empty area 110B, to descend so that the potting units 74 are adjacent to the semiconductor devices 120. Further, the underfill driving unit 76 may move the potting units 74 in a horizontal direction so that the underfill process is performed simultaneously for the semiconductor devices 120. In the present example, the potting unit disposed over the empty area 110B may not operate so as to prevent the underfill resin from being supplied into a punch hole 110C of the empty area 110B.

In accordance with an exemplary embodiment, the number of potting units 74 of the underfill module 70 may be vary. In some embodiments, to improve productivity of the semiconductor packages 100, the potting units 74 may have the same number as that of screen printing units 34 of the packaging module 30.

After the underfill process is performed by the underfill module 70, the flexible substrate 110 may be transferred into the packaging module 30 through the pre-curing module 80. The pre-curing module 80 may include a heater 82 for curing the underfill layers 140.

Referring to FIG. 16, the potting units 74 may supply the underfill resin to a portion of the top surface of the flexible substrate 110 that is adjacent to one or more side surfaces of the semiconductor devices 120. The underfill resin may permeate into a space between the flexible substrate 110 and the semiconductor device 120 by surface tension thereof. As described above, the underfill layer 140 formed between the flexible substrate 110 and the semiconductor device 120 may be cured at a temperature of approximately 150° C. while passing through the pre-curing module 80.

The underfill resin may include an epoxy resin, a curing agent, a curing accelerator, an inorganic filler, and combinations thereof. The epoxy resin may include a bisphenol A type epoxy resin, a bisphenol F type epoxy resin, a bisphenol S type epoxy resin, a naphthalene type epoxy resin, a phenol novolac type epoxy resin, a cresol novolac epoxy resin, and the like, and combinations thereof. An amine-based curing agent and an imidazole-based curing accelerator may be used as the curing agent and the curing accelerator, respectively.

Aluminum oxide may be used as the inorganic filler to improve the thermal conductivity of the underfill layer 140. The aluminum oxide may have a particle size in a range between approximately 0.01 μm and approximately 20 μm.

Referring to FIGS. 17 and 18, after the underfill layer 140 is formed, a heat dissipation layer 130 may be formed on the semiconductor device 120 and the flexible substrate 110. Since an example of a method of forming the heat dissipation layer 130 is substantially similar to that previously described above with reference to FIGS. 10 to 14, a redundant description of this exemplary method will be omitted.

Alternatively, the underfill process using the underfill resin may be performed after a die bonding process in which the semiconductor devices 120 are mounted on the flexible substrate 110. In this case, the semiconductors 120 may be packaged by using the packaging apparatus and method, which were previously described above with reference to FIGS. 1 to 14.

In accordance with the exemplary embodiments, the heat dissipation layer 130 may be formed on the flexible substrate 110 and the semiconductor device 120. The heat dissipation layer may function to dissipate heat generated by the semiconductor device 120. The semiconductor device 120 may be packaged by the heat dissipation layer 130. Particularly, the packaging process may be omitted on the empty area 110B of the flexible substrate 110 on which a semiconductor device 120 is not mounted. Thus, productivity of the packaging process of the flexible semiconductor package 100 may be significantly improved.

The heat dissipation layer 130 may improve in flexibility and adhesion due to the epichlorohydrin bisphenol A resin and the modified epoxy resin, and may have relatively higher thermal conductivity due to the heat dissipation filler. Accordingly, the heat dissipation efficiency from the semiconductor device 120 may be greatly improved by the heat dissipation layer 130. Particularly, since the heat dissipation layer 130 has improved flexibility and adhesion, the likelihood of a separation of the heat dissipation layer 130 from the flexible substrate 110 and the semiconductor 120 may be reduced while maintaining the flexibility of the flexible substrate 110.

Additionally, the underfill layer 140 may be formed with an improved thermal conductivity between the flexible substrate 110 and the semiconductor device 120, thereby more increasing the efficiency of heat dissipation from the semiconductor device 120.

Although methods and apparatuses for packaging semiconductor devices have been described with reference to the specific embodiments, it should be appreciated that they are not limited thereto. Therefore, it will be readily understood by those skilled in the art that various modifications and changes can be made thereto without departing from the spirit and scope of the present invention defined by the appended claims.

What is claimed is:

1. A method of packaging semiconductor devices mounted on a flexible substrate having a longitudinally extending tape shape and on which packaging areas are defined along an extending direction thereof, the method comprising:
transferring the flexible substrate through a packaging module;
detecting, from among the packaging areas, an empty area on which a semiconductor device is not mounted; and
forming a heat dissipation layer on at least one semiconductor device located in a processing region of the packaging module so as to package the semiconductor device,
wherein the heat dissipation layer is formed by coating the semiconductor device with a heat dissipation paint composition by using a screen printing process, and wherein a packaging process is omitted on the empty area.

2. The method of claim 1, wherein the forming of the heat dissipation layer comprises:
disposing a mask on the flexible substrate, wherein the mask defines an opening that exposes the semiconductor device and a portion of a top surface of the flexible substrate that is adjacent to the semiconductor device;
supplying the heat dissipation paint composition onto the mask; and
filling the opening with the heat dissipation paint composition using a squeegee.

3. The method of claim 1, wherein the processing region of the packaging module comprises a plurality of screen printing regions, and wherein the screen printing process on the remaining packaging areas is performed simultaneously on packaging areas located under the plurality of screen printing regions, other than the empty area.

4. The method of claim 3, wherein the screen printing regions are isolated from each other.

5. The method of claim 1, further comprising curing the heat dissipation layer formed on the semiconductor device.

6. The method of claim 1, further comprising forming an underfill layer filling a space between the flexible substrate and the semiconductor device.

7. The method of claim 6, wherein the underfill layer is formed by injecting an underfill resin into the space between the flexible substrate and the semiconductor device.

8. The method of claim 6, wherein the forming of the underfill layer comprises:
transferring the flexible substrate through an underfill module prior to forming the heat dissipation layer on the semiconductor device; and
forming the underfill layer between the packaging area of the flexible substrate and the semiconductor device located in a processing region of the underfill module, wherein forming of the underfill layer is omitted on the empty area.

9. The method of claim 8, wherein a plurality of packaging areas is located in the processing region of the underfill module, and wherein the underfill process is performed simultaneously on the semiconductor devices mounted on the remaining packaging areas in the processing region of the underfill module, except for the empty area.

10. The method of claim 6, further comprising curing the underfill layer.

11. The method of claim 1, wherein the heat dissipation paint composition comprises approximately 1 wt % to approximately 5 wt % of an epichlorohydrin bisphenol A resin, approximately 1 wt % to approximately 5 wt % of a modified epoxy resin, approximately 1 wt % to approximately 10 wt % of a curing agent, approximately 1 wt % to approximately 5 wt % of a curing accelerator and the remaining amount of a heat dissipation filler.

12. The method of claim 11, wherein the modified epoxy resin is a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), an urethane modified epoxy resin or a silicon modified epoxy resin.

13. The method of claim 11, wherein the curing agent is a novolac type phenolic resin.

14. The method of claim 11, wherein the curing accelerator is an imidazole-based curing accelerator or an amine-based curing accelerator.

15. The method of claim 11, wherein the heat dissipation filler comprises aluminum oxide having a particle size of approximately 0.01 μm to approximately 50 μm.

16. An apparatus of packaging semiconductor devices mounted on a flexible substrate having a longitudinally extending tape shape and on which packaging areas are defined along an extending direction thereof, the apparatus comprising:
an unwinder module configured to supply the flexible substrate;
a rewinder module configured to recover the flexible substrate;
a packaging module disposed between the unwinder module and the rewinder module to coat the semiconductor devices with a heat dissipation paint composition by using a screen printing process, thereby forming heat dissipation layers on the semiconductor devices; and
a control unit configured to detect an empty area on which a semiconductor device is not mounted from among the packaging areas and to control operations of the packaging module so that a packaging process is omitted on the empty area.

17. The apparatus of claim 16, wherein the packaging module comprises:
a packaging chamber;
a screen printing unit disposed in the packaging chamber, the screen printing unit comprising a mask defining an opening configured to apply the heat dissipation paint composition on the semiconductor devices, a nozzle configured to supply the heat dissipation paint composition on the mask, and a squeegee configured to fill the opening with the heat dissipation paint composition; and
a driving unit configured to vertically move the screen printing unit so as to be disposed on the flexible substrate and horizontally move the squeegee so as to fill the opening with the heat dissipation paint composition.

18. The apparatus of claim 16, further comprising a curing module configured to cure the heat dissipation layers.

19. The apparatus of claim 16, wherein the curing module comprises:
a curing chamber disposed between the packaging module and the rewinder module; and
a plurality of heaters disposed along a transfer path of the flexible substrate in the curing chamber to cure the heat dissipation layers.

20. The apparatus of claim 16, further comprising an underfill module configured to form underfill layers between the flexible substrate and the semiconductor devices.
